(19) United States
(12) Patent Application Publication
(10) Pub. No.: US 2023/0380077 A1
(43) Pub. Date: Nov. 23, 2023

(54) MULTI-LAYER CERAMIC PACKAGE HAVING A MULTILAYER CERAMIC BASE AND AT LEAST ONE INKJET PRINTED LAYER

(71) Applicant: Kyocera International, Inc., San Diego, CA (US)

(72) Inventors: Hiroshi MAKINO, San Diego, CA (US); Paul GARLAND, San Diego, CA (US)

(21) Appl. No.: 18/198,361

(22) Filed: May 17, 2023

Related U.S. Application Data
(60) Provisional application No. 63/344,500, filed on May 20, 2022.

(51) Int. Cl. H05K 3/46; H05K 1/02

(52) U.S. Cl. CPC H05K 3/4664; H05K 1/0298; H05K 2203/1126; H05K 2203/1476

(57) ABSTRACT

The examples set forth herein involve inkjet printing one or more layers on a multilayer ceramic base. In some examples, the multilayer ceramic base is fired in a first firing process before one or more inkjet printed layers are printed on the multilayer ceramic base to form a combination package comprising the multilayer ceramic base and the one or more inkjet printed layers. In further examples, the combination package is fired in a second firing process.

### CLAIM OF PRIORITY

The present application claims the benefit of priority to Provisional Application No. 63/344,500 entitled “MULTI-LAYER CERAMIC PACKAGE HAVING A CO-FIRED MULTILAYER AND POST-FIRED MULTILAYER COMBINATION”, docket number KII-SC PRO 00021 US, filed May 20, 2022, assigned to the assignee hereof and hereby expressly incorporated by reference in its entirety.

### FIELD

This invention generally relates to multi-layer ceramic packages, and more particularly to combination packages comprising a multilayer ceramic base and at least one inkjet printed portion.

### BACKGROUND

Co-fired ceramic devices are ceramic microelectronic devices in which the entire ceramic support structure and any conductive, resistive, and dielectric materials are fired in a kiln at the same time. These ceramic support structures are commonly called microelectronic packages and will usually house semiconductor devices as the main function. Passive devices including capacitors, inductors, resistors, transformers, and hybrid circuits can also be included in the manufacturing process or also housed in these packages. Although conventional multilayer ceramic processes provide for high productivity in the manufacture of multilayer ceramic packages, conventional multilayer ceramic processes have certain drawbacks due to the inherent layer structure of the processing and the limited accuracy of conventional green side processes and co-firing processes.

### SUMMARY

The examples set forth herein involve inkjet printing one or more layers on a multilayer ceramic base. In some examples, the multilayer ceramic base is fired in a first firing process before one or more inkjet printed layers are printed on the multilayer ceramic base to form a combination package comprising the multilayer ceramic base and the one or more inkjet printed layers. In further examples, the combination package is fired in a second firing process.

### BRIEF DESCRIPTION OF THE DRAWINGS

FIG. 1 is a block diagram showing a cross-section of an example of a multilayer ceramic base.

FIG. 2 is a block diagram showing a cross-section of an example of a combination package comprising the multilayer ceramic base of FIG. 1 and two inkjet printed layers.

FIG. 3 is a block diagram showing a cross-section of an example of a combination package comprising the multilayer ceramic base of FIG. 1 and a first inkjet printed layer comprising a first material and a second inkjet printed layer comprising a second material.

FIG. 4 is a block diagram showing a cross-section of an example of a combination package comprising the multilayer ceramic base of FIG. 1 and at least one inkjet printed layer having a first portion comprising a first material and a second portion comprising a second material.

FIG. 5 is a block diagram showing a cross-section of an example of a combination package comprising the multilayer ceramic base of FIG. 1 and at least one inkjet printed layer comprising an island structure.

FIG. 6 is a flowchart of an example of a method of producing a multilayer ceramic package.

### DETAILED DESCRIPTION

Co-fired ceramic devices are fabricated using a multilayer approach. The starting material is composite green tapes comprising ceramic particles mixed with polymer binders. The tapes are flexible and can be machined, for example, using cutting, milling, punching, and embossing. Metal structures can be added to the layers, commonly using filling and screen printing. Individual tapes are then bonded together in a lamination procedure before the devices are fired in a kiln.

Co-firing can be divided into low-temperature co-fired ceramic (LTCC) and high-temperature co-fired ceramic (HTCC) applications. Generally, low temperature means that the sintering temperature is below 1,000° C. (1,830° F.), while high temperature is around 1,600° C. (2,910° F.). The lower sintering temperature for LTCC materials is made possible through the addition of a glassy phase to the ceramic, which lowers its melting temperature. The co-firing process and temperature are selected based on the materials being fired in the co-firing process.

The processes that occur prior to firing are known as green processes or stages. In the firing process, the polymer part of the tape is combusted, and the ceramic particles sinter together, forming a hard and dense ceramic component. The process flow may also include plating and brazing and final backend processes prior to inspection, packing, and shipping.

Conventional multilayer ceramic processes provide for high productivity in the manufacture of multilayer ceramic packages. However, there are several drawbacks of conventional multilayer ceramic processes. First, conventional green side processes have an upper limit to their accuracy. Second, co-firing processes also have limited accuracy due to the material shrinkage that naturally occurs during the co-firing process. Third, the inherent layered nature of conventional processing precludes forming layers comprising multiple types of material, precludes formation of island structures, and may be prone to excess/wasted material.

The recent development of inkjet printing technology allows fabrication of multilayer ceramic structures using inkjet printing methods. The inkjet printing methods can achieve accurate structure in the green stages, but the challenge of the shrinkage that occurs during the firing process remains. Additionally, due to the nature of inkjet printing processes, the inkjet printing speeds are slow and are not conducive for mass production of multilayer ceramic packages.

The examples set forth herein involve inkjet printing one or more layers on a multilayer ceramic base. In some examples, the multilayer ceramic base is fired in a first firing process before one or more inkjet printed layers are printed on the multilayer ceramic base to form a combination package comprising the multilayer ceramic base and the one or more inkjet printed layers. In further examples, the combination package is fired in a second firing process.

By inkjet printing on the multilayer ceramic base, certain advantages may be achieved. For example, inkjet printing cannot be used to quickly print a large volume, which lowers process efficiency. Thus, overall process efficiency and accuracy can be improved by creating the multilayer ceramic base, utilizing conventional green processes, for portions of a device that have lower tolerance requirements, and inkjet printing can be utilized to print one or more layers, on the multilayer ceramic base, which have higher tolerance requirements or which are comprised of multiple different types of material.

Moreover, in some examples, the one or more inkjet printed layers, which are printed on the previously co-fired multilayer ceramic base, are fired in a second firing process. In these examples, during the second firing process, the multilayer ceramic base does not shrink since the multilayer ceramic base already went through a first firing process in which shrinkage may have already occurred along the x-y planes (e.g., length and width) of the layers of the multilayer ceramic base. Due to the previous shrinking of the multilayer ceramic base, the inkjet printed layers will not generally experience shrinkage variation from the second firing process along the x-y planes of the inkjet printed layers, which improves dimensional accuracy of the inkjet printed layers. However, in some examples, the inkjet printed layers may experience shrinkage in the z direction (e.g., thickness of the inkjet printed layer). The two-step firing process of the co-fired multilayer ceramic base and the inkjet printed layers provides accurate x-y dimensions for the inkjet printed areas. Accurate x-y direction dimensions are highly desirable, for example, in radio frequency (RF) related packages to maintain accurate RF performance.

Furthermore, inkjet printing processes on a multilayer ceramic base overcome the difficulties in combining multilayer LTCC and multilayer HTCC in one package due to differences in the melting points for LTCC materials and HTCC materials. As will be described more fully below, an HTCC firing of a multilayer ceramic base followed by an LTCC firing of printed inkjet layers provides a combination package with accurate and dimension-consistent “island” structures, in some examples. Although some examples herein may describe a particular type(s) and/or sequence of firing processes to be used, any of the examples herein may be modified to use any suitable alternative type(s) and/or sequence of firing processes.

Moreover, although the examples described herein generally refer to a first and a second firing process, there may be one or more additional firing processes that could be used in creating the combination package, in other examples. For example, in the examples in which multiple materials are used in the inkjet printed layers, each material may be fired using a different firing process (e.g., an LTCC and an HTCC; or two different types of LTCC).

Furthermore, although many of the examples described herein refer to firing processes, laser sintering may be used instead of, or in addition to, the firing processes, in some examples. As used herein, laser sintering refers to a process where material is deposited and cured with a laser at essentially the same time.

Although the different examples described herein may be discussed separately, any of the features of any of the examples may be added to, omitted from, or combined with any other example. Similarly, any of the features of any of the examples may be performed in parallel or performed in a different manner/order than that described or shown herein.

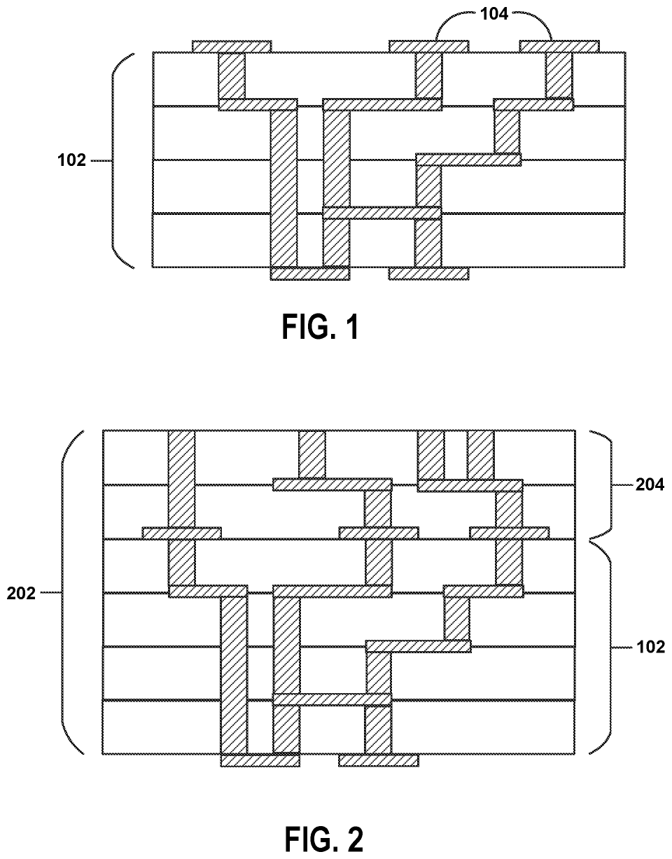

FIG. 1 is a block diagram showing a cross-section of an example of a multilayer ceramic base. In the example shown in FIG. 1, multilayer ceramic base 102 comprises four layers and conductive materials 104, such as vias and interconnects, which are shown in FIG. 1 as the hatched portions of multilayer ceramic base 102. In other examples, multilayer ceramic base 102 may have any other suitable number of layers and may have a different number and/or configuration of conductive materials 104 than those shown in FIG. 1.

Although multilayer ceramic base 102 would generally be produced using conventional green processes, one or more of the ceramic layers of multilayer ceramic base 102 could be inkjet printed in addition to or as a substitute for screen printing during the green process to improve accuracy, in other examples. In further examples, inkjet printing can be used for all of the ceramic layers of multilayer ceramic base 102 for improved dimensional accuracy. However, in these examples, the co-firing of the inkjet printed layers of multilayer ceramic base 102 would result in shrinkage variations in the x-y planes. In addition, inkjet printing of large volumes of ceramic layers cannot be produced quickly and would decrease overall process efficiency.

FIG. 2 is a block diagram showing a cross-section of an example of a combination package comprising the multilayer ceramic base of FIG. 1 and two inkjet printed layers. In the example shown in FIG. 2, combination package 202 comprises multilayer ceramic base 102 and two inkjet printed layers 204 that have been printed on multilayer ceramic base 102. Although FIG. 2 shows two inkjet printed layers, one or more inkjet printed layers may be printed on multilayer ceramic base 102. As in FIG. 1, conductive materials, such as vias and interconnects, are shown in FIG. 2 as the hatched portions of multilayer ceramic base 102 and inkjet printed layers 204. In other examples, combination package 202 may have any other suitable number of layers and may have a different number and/or configuration of conductive materials than those shown in FIG. 2.

In the example shown in FIG. 2, multilayer ceramic base 102 has been fired in a first firing process. After the first firing process, inkjet printed layers 204 have been printed on multilayer ceramic base 102 to form combination package 202 comprising multilayer ceramic base 102 and inkjet printed layers 204. Although not explicitly shown in FIG. 2, ceramic paste is printed on multilayer ceramic base 102 prior to printing inkjet printed layers 204, in some examples.

Combination package 202 is fired in a second firing process after inkjet printed layers 204 are printed on multilayer ceramic base 102. In some examples, a first temperature associated with the first firing process is equal to or greater than a second temperature associated with the second firing process. More specifically, the first firing process may be a High-Temperature Co-fired Ceramic (HTCC) firing process, and the second firing process may be a Low-Temperature Co-fired Ceramic (LTCC) firing process, in some examples. In other examples, a first temperature associated with the first firing process is less than a second temperature associated with the second firing process.

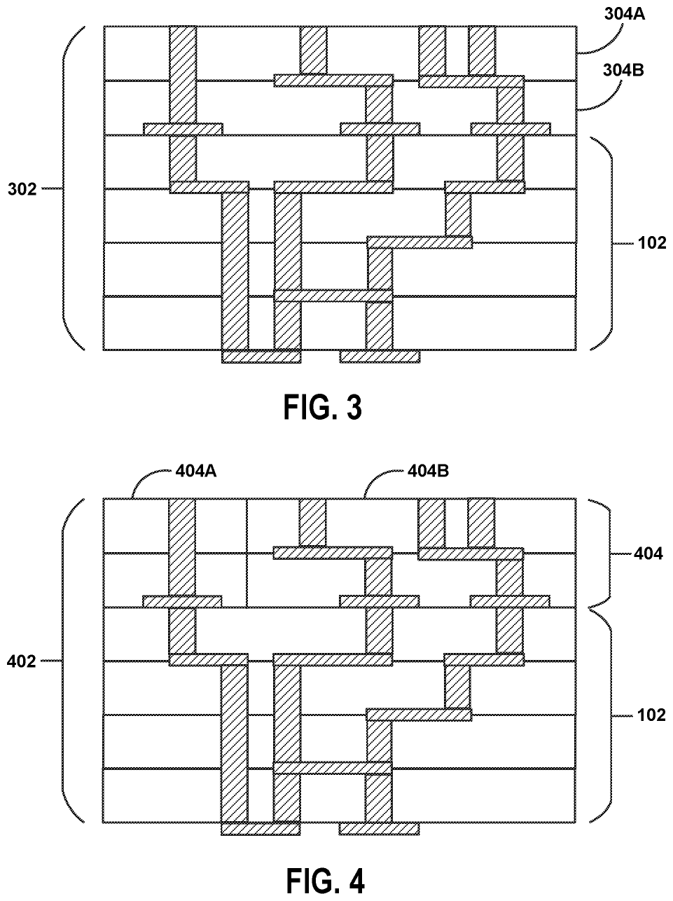

In some examples, the inkjet printed layers collectively comprise at least two different materials. In some of these examples, at least one inkjet printed layer comprises a first layer of a first material and a second layer of a second material, as shown in FIG. 3. In other examples, at least one of the inkjet printed layers comprises a layer having a first portion and a second portion, such that the first portion comprises a first material and the second portion comprises a second material, as shown in FIG. 4.

FIG. 3 shows a block diagram of a cross-section of an example of combination package 302 comprising multilayer ceramic base 102 of FIG. 1 and a first inkjet printed layer 304A comprising a first material and a second inkjet printed layer 304B comprising a second material. In some examples, the first material and the second material may be selected from the following groups: Group 1—Insulators (non-electrical conductors), HTCC, LTCC, Glassy materials, high dielectrics, etc.; Group 2—Conductors (electrical conductors), Tungsten, Molybdenum, Copper, Nickel, Silver, etc.; Group 3—Resistors (poor conductors), Ruthenium Oxide, Ni-Chrome, etc.; Group 4—Thermal conductors, (may be either electrically conductive, or not), Aluminum Nitride (AlN), Copper/Mo mixture, etc.; Group 4—Semiconductors. Of course, any other suitable materials may be utilized, in other examples.

FIG. 4 is a block diagram showing a cross-section of an example of combination package 402 comprising multilayer ceramic base 102 of FIG. 1 and two inkjet printed layers 404. The top inkjet printed layer has first portion 404A comprising a first material and second portion 404B comprising a second material. In some examples, the first material comprises a dielectric material, and the second material comprises a conductive material. One potential advantage of inkjet printing is that it allows for different materials to be placed close to each other on the same plane (e.g., layer), which is not possible in a conventional lamination process.

In some examples, the first material and the second material may be selected from the following groups: Group 1—Insulators (non-electrical conductors), HTCC, LTCC, Glassy materials, high dielectrics, etc.; Group 2—Conductors (electrical conductors), Tungsten, Molybdenum, Copper, Nickel, Silver, etc.; Group 3—Resistors (poor conductors), Ruthenium Oxide, Ni-Chrome, etc.; Group 4—Thermal conductors, (may be either electrically conductive, or not), Aluminum Nitride (AlN), Copper/Mo mixture, etc.; Group 4—Semiconductors. Of course, any other suitable materials may be utilized, in other examples.

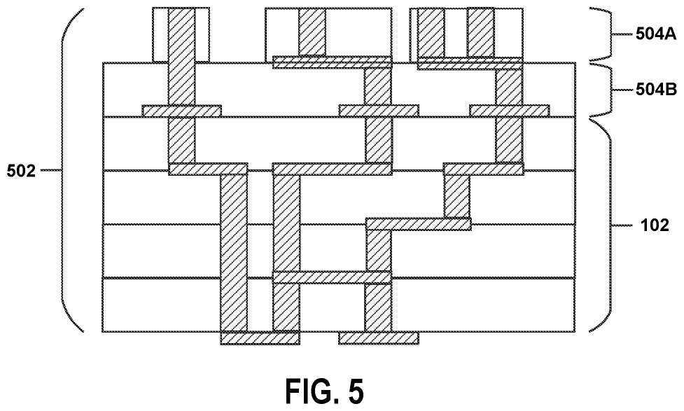

FIG. 5 is a block diagram showing a cross-section of an example of combination package 502 comprising multilayer ceramic base 102 of FIG. 1 and inkjet printed layer 504A comprising multiple island structures. In the example of FIG. 5, inkjet printed layer 504B does not comprise any island structures. The separate inkjet printed components, or island structures, can maintain accurate placement and dimensions during a second firing process. As used herein, an “island structure” refers to a structural component that protrudes relative to a surface of an adjacent layer and that does not intersect a vertical plane that extends from an outer edge of a base ceramic layer(s). In some examples, an island structure may comprise an antenna or a microwave absorber.

Similar to the example shown in FIG. 2, combination package 502 is fired in a second firing process after inkjet printed layers 504A, 504B are printed on multilayer ceramic base 102. In some examples, a first temperature associated with the first firing process is equal to or greater than a second temperature associated with the second firing process. More specifically, the first firing process may be a High-Temperature Co-fired Ceramic (HTCC) firing process, and the second firing process may be a Low-Temperature Co-fired Ceramic (LTCC) firing process. In other examples, a first temperature associated with the first firing process is less than a second temperature associated with the second firing process.

In some examples, different materials can be used for different inkjet printed layers. For example, one inkjet printed layer may provide strength for the package structure, and another inkjet printed layer may provide performance characteristics for particular applications (e.g., RF performance characteristics). In further examples, a single inkjet printed layer may have an RF layer section and an alumina layer section adjacent to the RF layer section.

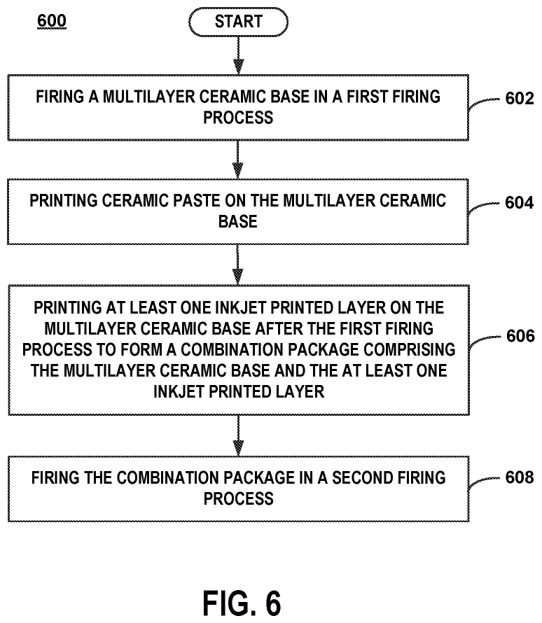

FIG. 6 is a flowchart of an example of a method 600 of producing a multilayer ceramic package. At step 602, a multilayer ceramic base is fired in a first firing process. At step 604, ceramic paste is printed on the multilayer ceramic base. At step 606, at least one inkjet printed layer is printed on the multilayer ceramic base after the first firing process to form a combination package comprising the multilayer ceramic base and the at least one inkjet printed layer. At step 608, the combination package is fired in a second firing process.

In other examples, one or more of the steps of method 600 may be omitted, combined, performed in parallel, or performed in a different order than that described herein or shown in FIG. 6. In still further examples, additional steps may be added to method 600 that are not explicitly described in connection with the example shown in FIG. 6.

Clearly, other embodiments and modifications of this invention will occur readily to those of ordinary skill in the art in view of these teachings. The above description is illustrative and not restrictive. This invention is to be limited only by the following claims, which include all such embodiments and modifications when viewed in conjunction with the above specification and accompanying drawings. The scope of the invention should, therefore, be determined not with reference to the above description, but instead should be determined with reference to the appended claims along with their full scope of equivalents.

1. A method for producing a multilayer ceramic package comprising:
firing a multilayer ceramic base in a first firing process;
printing at least one inkjet printed layer on the multilayer ceramic base after the first firing process to form a combination package comprising the multilayer ceramic base and the at least one inkjet printed layer; and
firing the combination package in a second firing process.

2. The method of claim 1, wherein printing the at least one inkjet printed layer comprises printing with at least two different materials.

3. The method of claim 2, wherein printing the at least one inkjet printed layer comprises printing a first layer of a first material and printing a second layer of a second material.

4. The method of claim 2, wherein printing the at least one inkjet printed layer comprises printing a layer having a first portion and a second portion, the first portion comprising a first material and the second portion comprising a second material.

5. The method of claim 4, wherein the first material comprises a dielectric material and the second material comprises a conductive material.

6. The method of claim 1, wherein a first temperature associated with the first firing process is equal to or greater than a second temperature associated with the second firing process.

7. The method of claim 1, wherein a first temperature associated with the first firing process is less than a second temperature associated with the second firing process.

8. The method of claim 1, wherein printing the at least one inkjet printed layer comprises printing an island structure.

9. The method of claim 8, wherein a first temperature associated with the first firing process is equal to or greater than a second temperature associated with the second firing process.

10. The method of claim 8, wherein a first temperature associated with the first firing process is less than a second temperature associated with the second firing process.

11. The method of claim 1, further comprising:
prior to printing the at least one inkjet printed layer, printing ceramic paste on the multilayer ceramic base.

12. A combination package comprising:
a multilayer ceramic base that has been fired in a first firing process; and
at least one inkjet printed layer printed on the multilayer ceramic base after the first firing process, the combination package fired in a second firing process after the at least one inkjet printed layer is printed on the multilayer ceramic base.

13. The combination package of claim 12, wherein the at least one inkjet printed layer comprises at least two different materials.

14. The combination package of claim 13, wherein the at least one inkjet printed layer comprises a first layer of a first material and a second layer of a second material.

15. The combination package of claim 13, wherein the at least one inkjet printed layer comprises a layer having a first portion and a second portion, the first portion comprising a first material and the second portion comprising a second material.

16. The combination package of claim 15, wherein the first material comprises a dielectric material and the second material comprises a conductive material.

17. The combination package of claim 12, wherein a first temperature associated with the first firing process is less than a second temperature associated with the second firing process.

18. The combination package of claim 12, wherein a first temperature associated with the first firing process is equal to or greater than a second temperature associated with the second firing process.

19. The combination package of claim 18, wherein the first firing process is a High-Temperature Co-fired Ceramic (HTCC) firing process, and the second firing process is a Low-Temperature Co-fired Ceramic (LTCC) firing process.

20. The combination package of claim 12, wherein the at least one inkjet printed layer comprises an island structure.

21. The combination package of claim 20, wherein a first temperature associated with the first firing process is equal to or greater than a second temperature associated with the second firing process.

22. The combination package of claim 20, wherein a first temperature associated with the first firing process is less than a second temperature associated with the second firing process.

23. The combination package of claim 12, further comprising:
ceramic paste printed between the multilayer ceramic base and the at least one inkjet printed layer.

24. A combination package comprising:
a multilayer ceramic base that has been formed using a laser sintering process; and
at least one inkjet printed layer printed on the multilayer ceramic base after the laser sintering process, the combination package fired in a firing process after the at least one inkjet printed layer is printed on the multilayer ceramic base.
